(19) United States
(12) Patent Application Publication
(10) Pub. No.: US 2008/0088005 A1
(43) Pub. Date: Apr. 17, 2008

(54) SIP package with small dimension

(75) Inventor: Ronald Takao Iwata, Hsinchu (TW)

Correspondence Address: TROXELL LAW OFFICE PLLC, SUITE 1404, 5205 LEESBURG PIKE, FALLS CHURCH, VA, 22041, US

(73) Assignee: POWERTECH TECHNOLOGY INC.

(21) Appl. No.: 11/581,084

(22) Filed: Oct. 16, 2006

(51) Int. Cl. H01L 23/48

(52) U.S. Cl. 257/690; 257/E23.01

(57) ABSTRACT

A SIP package with a small dimension integrates one or more small size chips. The small size chips are disposed on a back side of a carrying chip and are encapsulated by an encapsulant. The SIP package further includes a substrate having a slot, an encapsulant and a plurality of bonding wires. The carrying chip is disposed on the substrate and the bonding pads of the carrying chip are aligned within the slot. A back side pattern is formed on the back side of the carrying chip. The chip-attached area of the small size chips is smaller than half of that of the back side of the carrying chip. Besides, the back side pattern is connected with a plurality of transfer fingers or a plurality of PTHs at the periphery of the back side for electrically connecting the small size chips to the substrate. Accordingly, the bonding wires used for connecting the small size chips can be shortened and regulated to achieve miniaturization of SIP package without increasing package size and thickness.

### FIELD OF THE INVENTION

The present invention is generally relating to a multi-chip IC package, more particularly to a SIP (System-In-Package) package with small dimension.

### BACKGROUND OF THE INVENTION

Conventionally electronic packages are single chip packages and are surface-mounted to a PCB (Printed Circuit Board) respectively. In order to accord with the trend toward portable requirement and miniaturizing development of electronic device, various improvements within semiconductor packages have been made in recent years, for example numerous chips and more and more micro electronic components are integrated in a same IC package to save SMT space on PCB.

Referring to FIG. 1, a well known integrated circuit package 100, such as window BGA package, mainly comprises a substrate 110, a chip 120, an encapsulant 130, a plurality of solder balls 140 and a plurality of bonding wires 150. The substrate 110 has an upper surface 111, a lower surface 112 and a slot 113. The chip 120 with its active surface 121 facing toward the substrate 110 is disposed on the upper surface 111 of the substrate 110. The chip 120 has a plurality of bonding pads 123 aligned within the slot 113 of the substrate 110 and the bonding wires 150 are utilized to electrically connect the bonding pads 123 to the substrate through the slot 113. The encapsulant 130 is formed over the upper surface 111 and in the slot 130 of the substrate 110 to encapsulate the chip 120 and the bonding wires 150. The solder balls 140 are typically disposed on the lower surface 112 of the substrate 110 and utilized for surface-mounting the integrated circuit package 100 onto the PCB 10. One or more other IC packages 20 comprising small size chips 21 should be mounted onto the PCB 10 in order to complete entire electrical function, however, the PCB 10 is required more SMT space for disposing the IC packages 20. Conductive path electrically between the small size chip 21 and the chip 120 of the integrated circuit package 100 is also longer.

Another conventional window BGA package with multi-chip back-to-back stack configuration is shown. An upper layer-chip has a same size and same function with a lower layer-chip and is back-to-back stacked on back side of the lower layer-chip. Bonding wires directly connect the upper layer-chip to the substrate. However, smaller the lower layer-chip is changed in size, longer the bonding wires become. Wire sweeping also becomes a serious problem. Moreover, the package becomes thicker because it is necessary for a thicker encapsulant to encapsulate the bonding wires having a higher loop.

### SUMMARY OF THE INVENTION

In order to solve the problems mentioned above, the primary object of the present invention is to provide a SIP (System-In-Package) package with small dimension, integrating one or more small size chips on back side of a carrying chip to form a window BGA system package without increasing package size and thickness thereby reaching SIP with small size and shortening electrically conductive path between chips.

One aspect of the present invention provides a SIP package with small dimension including a substrate, a carrying chip, one or more small size chips and an encapsulant. The substrate has an upper surface, a lower surface and a slot. The carrying chip has an active surface and a back side, the active surface faces toward the substrate allowing a plurality of bonding pads of the carrying chip to align within the slot. The small size chips have a chip-attached area smaller than half of that of the back side and the encapsulant is formed over the upper surface of the substrate to encapsulate the carrying chip and the small size chip. A back side pattern is formed on the back side of the carrying chip and has a plurality of transfer fingers formed at the periphery of the back side or is connected with a plurality of PTHs (Plated Through Holes) in the carrying chip for electrically connecting the small size chips to the substrate.

With respect to the SIP package mentioned above, it further comprises a plurality of first bonding wires and a plurality of second bonding wires, the first bonding wires electrically connect the small size chips to the back side pattern, and the second bonding wires electrically connect the transfer fingers to the substrate.

With respect to the SIP package mentioned above, it further comprises a plurality of third bonding wires electrically connecting the bonding pads of the carrying chip to the substrate through the slot.

With respect to the SIP package mentioned above, it further comprises at least a bonding wire disposed on the back side of the carrying chip to jumper connect the back side pattern across one or more traces.

With respect to the SIP package mentioned above, it further comprises a plurality of solder balls disposed on the lower surface of the substrate.

With respect to the SIP package mentioned above, the carrying chip may be a memory chip and the small size chips may be micro controller chips, logic chips or RF (Radio Frequency) chips.

With respect to the. SIP package mentioned above, it further comprises one or more passive components that are disposed at the periphery of the upper surface of the substrate and encapsulated by the encapsulant.

With respect to the SIP package mentioned above, the active surface of the carrying chip may occupy more than 70% of the upper surface of the substrate in area.

### DESCRIPTION OF THE DRAWINGS

FIG. 1 is a cross-sectional view of a known integrated circuit package after mounting process.

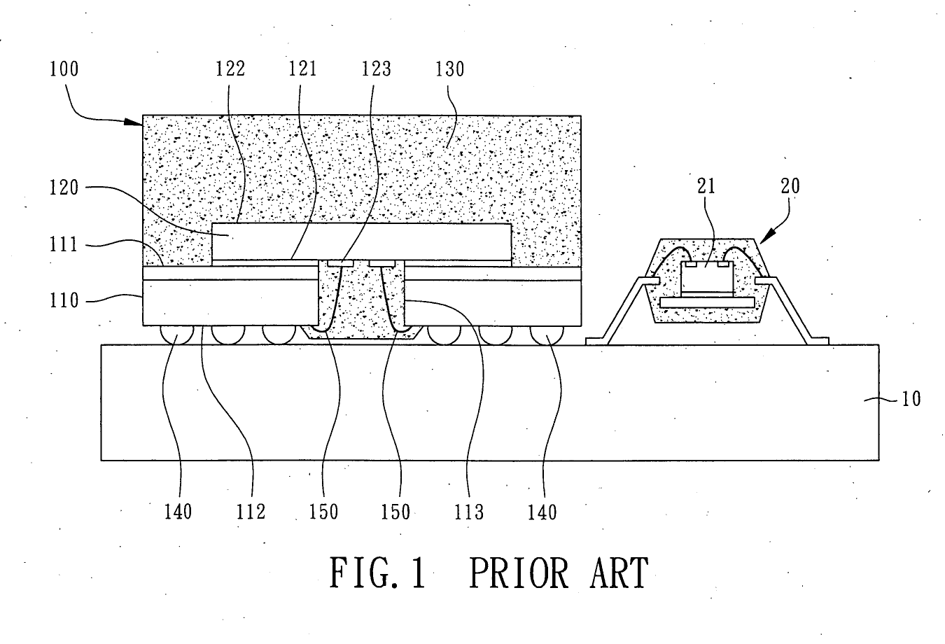

FIG. 2 is a cross-sectional view of a SIP package with small dimension in accordance with the first embodiment of the present invention.

FIG. 3 is a plan view of the SIP package in accordance with the first embodiment of the present invention.

FIG. 4 is a cross-sectional view of another SIP package with small dimension in accordance with the second embodiment of the present invention.

FIG. 5 is a plan view of the SIP package with small dimension in accordance with the second embodiment of the present invention.

### DETAILED DESCRIPTION OF THE INVENTION

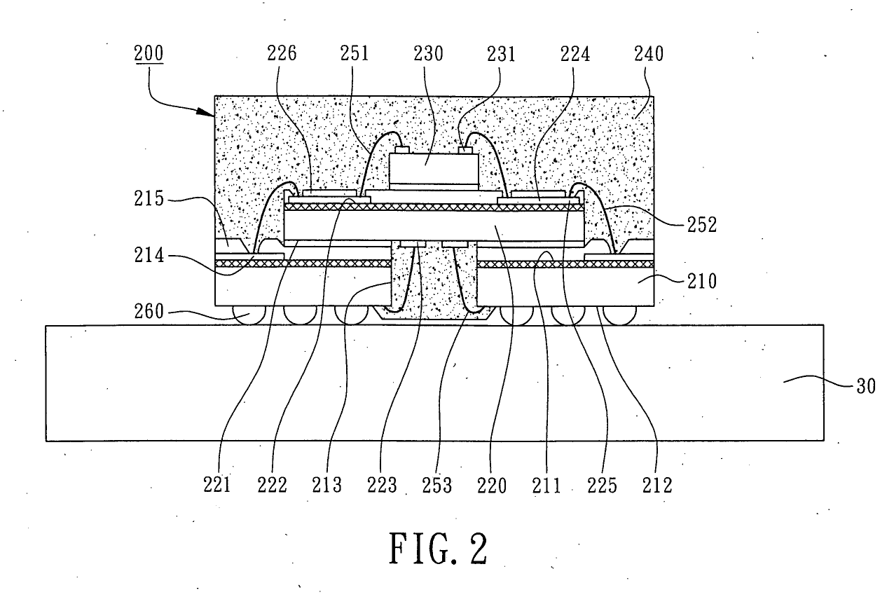

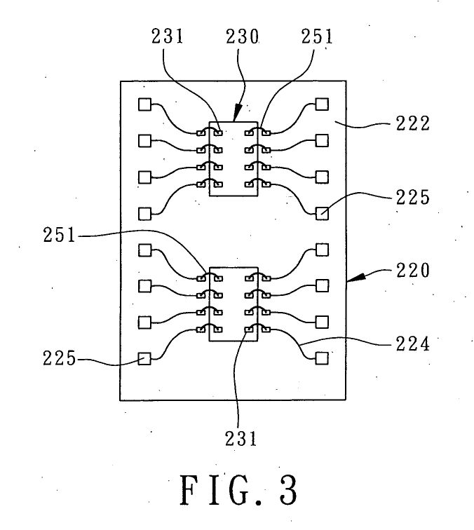

In the first embodiment of the present invention, as showed in FIGS. 2 and 3, a SIP package 200 mainly comprises a substrate 210, a carrying chip 220, one or more small size chips 230 and an encapsulant 240. The substrate 210 generally may be a multi-layer PCB and has an upper surface 211, a lower surface 212 and a slot 213. A plurality of fingers 214 is formed on the upper surface 211 and a solder resist layer 215 partially covers the traces that connect to the fingers 214. A plurality of fingers and a plurality of ball pads (not showed in the drawings) are formed on the lower surface 212.

The carrying chip 220 is disposed on the upper surface 211 of the substrate 200. The carrying chip 220 has an active surface 221 and a back side 222 opposing to the active surface 221. The active surface 221 is a surface with a plurality of integrated circuit components (not showed in the drawings) formed and the carrying chip 220 also has a plurality of bonding pads 223 on the active surface 221 serving as external electrodes. While performing chip-attaching process, the active surface 221 faces toward the substrate 210 allowing the bonding pads 223 to align within the slot 213. A plurality of third bonding wires 253 electrically connect the bonding pads 223 of the carrying chip 220 to the substrate 210 through the slot 213. Preferably, the active surface 221 of the carrying chip 220 occupies more than 70% of the upper surface 211 of the substrate 210 in area that achieves CSP (Chip Scale Package) in size. In this embodiment, the carrying chip 220 may be a memory chip.

The small size chips 230 are disposed on the back side 222 of the carrying chip 220 and the chip-attached area thereof is smaller than half of that of the back side 222. In this embodiment, the small size chip 230 may be micro controller chips, logic chips or RF chips, which may be packaged into SIP of various functions.

Referring to FIG. 3, the carrying chip 220 further includes a back side pattern 224 formed on the back side 222 of the carrying chip 220 to electrically connect the small size chips 230 to the substrate 210 and shorten length of bonding wires 252. The back side pattern 224 can be formed by applying existent integrated circuit fabricating process, in which it is formed during wafer fabrication process before the carrying chip 220 is sawed to separate. In addition, the carrying chip 220 further includes a passivation layer 226 on the back side 222 to cover the trace sections of the back side pattern 224, which may be made of PI, BCB or a solder resist layer.

Also, the back side pattern 224 has a plurality of transfer fingers 225 formed at the periphery of the back side 222 for electrically connecting the small size chips 230 to the substrate 210. The bonding pads 231 on the small size chips 230 are electrically connected to the back side pattern 224 via a plurality of first bonding wires 251 and also the transfer fingers 225 of the back side pattern 224 are electrically connected to the fingers 214 of the substrate 210 via a plurality of second bonding wires 252. Accordingly, loop height of the first bonding wires 251 will be reduced, and the wire length of the second bonding wires 252 will be shorter and regulated.

The encapsulant 240 is formed over the upper surface 211 of the substrate 210 to encapsulate the carrying chip 220, the small size chips 230, the first bonding wires 251 and the second bonding wires 252. Besides, the encapsulant 240 may further be formed in the slot 213 to encapsulate the third bonding wires 253. In this embodiment, the SIP package 200 further comprises a plurality of solder balls 260 disposed on the lower surface 212 of the substrate 210 to serve as external connections.

As a result, the small size chips 230 are integrated onto the back side 222 of the carrying chip 220 to form a SIP package with window BGA configuration, that decreases the length of used bonding wires to achieve miniaturization of SIP package and shorten conductive paths electrically between the carrying chip 220 and the small size chips 230 without increasing package size and thickness, and may even be surface mounted on a PCB 30 with still smaller size.

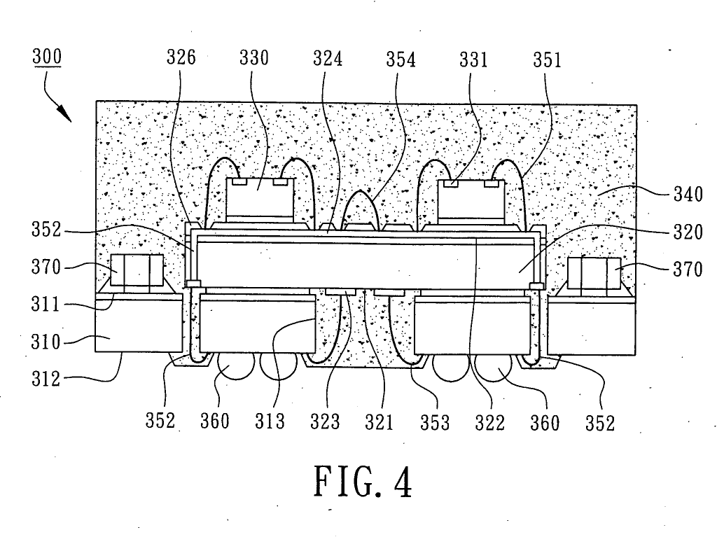

The second embodiment of the present invention is illustrated as showed in FIG. 4. Another SIP package 300 mainly comprises a substrate 310, a carrying chip 320, one or more small size chips 330 and an encapsulant 340. The substrate 310 has an upper surface 311, a lower surface 312 and a slot 313. The carrying chip 320 is disposed on the upper surface 311 of the substrate 310 and has an active surface 321 and a back side 322. The active surface 321 faces toward the substrate 310 that allows a plurality of bonding pads 323 of the carrying chip 320 to align within the slot 313. The bonding pads 323 are electrically connected to the substrate 310 via a plurality of third bonding wires 353 through the slot 313. The small size chips 330 are disposed on the back side 322 of the carrying chip 320 and the chip-attached area of the small size chips 330 is smaller than half of that of the back side 322 in area. The encapsulant 340 is formed over the upper surface 311 of the substrate 310 to encapsulate the carrying chip 320 and the small size chips 330. The carrying chip 320 further includes a back side pattern 324 which is formed on the back side 322 of the carrying chip 320 and connects to a plurality of PTHs 325 (Plated Through Holes) in the carrying chip 320 that are located at the periphery of the back side 322. The bonding pads 331 on the small size chips 330 are electrically connected to the back side pattern 324 via a plurality of first bonding wires 351 and also the PTHs 325 are electrically connected to the substrate 310 via a plurality of second bonding wires 352 so as to perform electrical interconnections between the small size chips 330 and the substrate 310. Moreover, at least partial signals from the small size chips 330 can be directly transmitted to the inner integrated circuit of the carrying chip 320 via the PTHs 352 to obtain a still faster transmission.

In this embodiment, the SIP package 300 further comprises a plurality of solder balls 360 disposed on the lower surface 312 of the substrate 310 to act as external connections. In addition, the SIP package 300 may further comprises one or more passive components 370 that is disposed at the periphery of the upper surface 311 of the substrate 310 and encapsulated by the encapsulant 340.

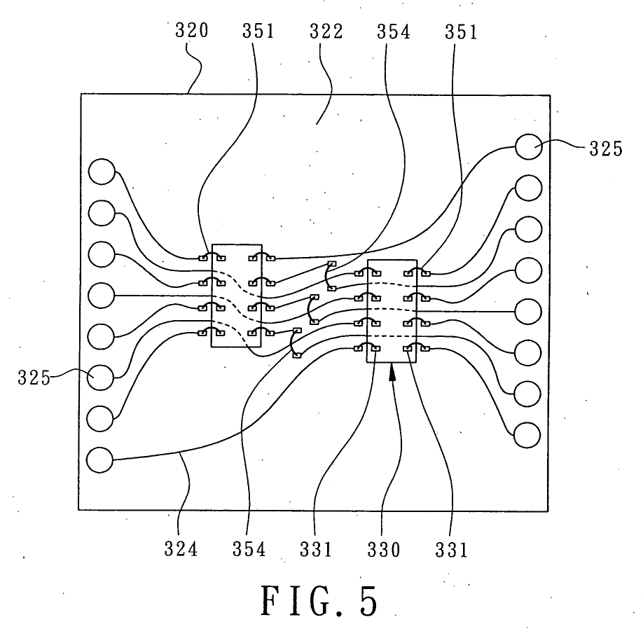

Referring to FIG. 5, the SIP package 300 preferably further comprises a plurality of fourth bonding wires 354 disposed on the back side 322 of the carrying chip 320 to jumper connect the back side pattern 324 across one or more traces of the back side pattern 324 without using multi-layer back side trace. That is to say, the back side pattern 324 may be single layer structure on the back side 322.

While the present invention has been particularly illustrated and described in detail with respect to the preferred embodiments thereof, it will be clearly understood by those skilled in the art that various changed in form and details may be made without departing from the spirit and scope of the present invention.

What is claimed is:

1. A SIP package comprising:
a substrate having an upper surface, a lower surface and a slot;
a carrying chip disposed on the upper surface of the substrate, the carrying chip having an active surface, a back side and a plurality of bonding pads on the active surface, the active surface facing toward the substrate to allow the -bonding pads to align within the slot;
one or more small size chips disposed on the back side of the carrying chip, the chip-attached area of the small size chips being smaller than half of that of the back side; and
an encapsulant formed over the upper surface of the substrate to encapsulate the carrying chip and the small size chips;
wherein the carrying chip further includes a back side pattern formed on the back side and has a plurality of transfer fingers formed at the periphery of the back side for electrically connecting the small size chips to the substrate.

2. The SIP package in accordance with claim 1, further comprising a plurality of first bonding wires electrically connecting the small size chips to the back side pattern and a plurality of second bonding wires electrically connecting the transfer fingers of the back side pattern to the substrate.

3. The SIP package in accordance with claim 2, further comprising a plurality of third bonding wires electrically connecting the bonding pads of the carrying chip to the substrate through the slot.

4. The SIP package in accordance with claim 3, wherein the encapsulant is further formed in the slot to encapsulate the third bonding wires.

5. The SIP package in accordance with claim 1, further comprising at least a bonding wire disposed on the back side of the carrying chip to jumper connect the back side pattern across one or more traces.

6. The SIP package in accordance with claim 1, further comprising a plurality of solder balls disposed on the lower surface of the substrate.

7. The SIP package in accordance with claim 1, wherein the carrying chip is a memory chip and the small size chips are micro controller chips, logic chips or RF chips.

8. The SIP package in accordance with claim 1, further comprising one or more passive components disposed at the periphery of the upper surface of the substrate and encapsulated by the encapsulant.

9. The SIP package in accordance with claim 1, wherein the active surface of the carrying chip occupies more than 70% of the upper surface of the substrate in area.

10. The SIP package in accordance with claim 1, wherein the carrying chip further includes a passivation layer on the back side to cover the back side pattern.

11. A SIP package comprising:
a substrate having an upper surface, a lower surface and a slot;
a carrying chip disposed on the upper surface of the substrate, the carrying chip having an active surface, a back side and a plurality of bonding pads on the active surface, the active surface facing toward the substrate to allow the bonding pads to align within the slot;
one or more small size chips disposed on the back side of the carrying chip, the chip-attached area of the small size chips being smaller than half of that of the back side; and
an encapsulant formed over the upper surface of the substrate to encapsulate the carrying chip and the small size chips;
wherein the carrying chip further includes a back side pattern formed on the back side of the carrying chip and a plurality of PTHs at the periphery of the back side connecting the back side pattern for electrically connecting the small size chips to the substrate.

12. The SIP package in accordance with claim 11, further comprising a plurality of first bonding wires electrically connecting the small size chips to the back side pattern and a plurality of second bonding wires electrically connecting the PTHs to the substrate.

13. The SIP package in accordance with claim 12, further comprising a plurality of third bonding wires electrically connecting the bonding pads of the carrying chip to the substrate through the slot.

14. The SIP package in accordance with claim 13, wherein the encapsulant is further formed in the slot to encapsulate the third bonding wires.

15. The SIP package in accordance with claim 11, further comprising at least a bonding wire disposed on the back side of the carrying chip to jumper connect the back side pattern across one or more traces.

16. The SIP package in accordance with claim 11, further comprising a plurality of solder balls disposed on the lower surface of the substrate.

17. The SIP package in accordance with claim 11, wherein the carrying chip is a memory chip and the small size chips are micro controller chips, logic chips or RF chips.

18. The SIP package in accordance with claim 11, further comprising one or more passive components disposed at the periphery of the upper surface of the substrate and encapsulated by the encapsulant.

19. The SIP package in accordance with claim 11, wherein the active surface of the carrying chip occupies more than 70% of the upper surface of the substrate in area.

20. The SIP package in accordance with claim 11, wherein the carrying chip further includes a passivation layer on the back side to cover the back side pattern.
